(19) United States
(12) Patent Application Publication
(10) Pub. No.: US 2026/0303086 A1
(43) Pub. Date: Oct. 1, 2026

(54) SEMICONDUCTOR DEVICE

(71) Applicant: Renesas Electronics Corporation, Tokyo (JP)

(72) Inventor: Toshiki KIRYU, Tokyo (JP)

(21) Appl. No.: 19/549,661

(22) Filed: Feb. 25, 2026

Related U.S. Application Data
(60) Provisional application No. 63/781,433, filed on Apr. 1, 2025.

(30) Foreign Application Priority Data
Aug. 25, 2025 (JP) 2025-139904

(51) Int. Cl. H03K 17/22; G06F 1/08; G06F 1/24

(52) U.S. Cl. CPC H03K 17/22; G06F 1/08; G06F 1/24

(57) ABSTRACT

An internal reset generation circuit asserts a reset request signal when a reset factor is detected. A pulse generation circuit generates a reset-out drive pulse signal, and controls a switch to an ON state/OFF state during an assertion period/negation period of the reset-out drive pulse signal. In more detail, a reset-out period setting register holds a count setting value representing a length of the assertion period of the reset-out drive pulse signal. A counter counts a clock signal starting from assertion of the reset request signal until the count setting value is reached, thereby generating the reset-out drive pulse signal.

### CROSS-REFERENCE TO RELATED APPLICATIONS

The disclosures of U.S. Patent Provisional Application No. 63/781,433 filed on Apr. 1, 2025 and Japanese Patent Application No. 2025-139904 filed on Aug. 25, 2025 including the specification, drawings and abstract are incorporated herein by reference in their entirety.

### BACKGROUND

The present invention relates to a semiconductor device, and more particularly to a semiconductor device having a function of resetting an external device.

There is disclosed a technique listed below.

[Patent Document 1] Japanese Unexamined Patent Application Publication No. 2014-32558

Patent Document 1 discloses a semiconductor device capable of returning from a reset state in a safer manner, more specifically, an MCU. This MCU includes a CVM and an MCU reset control circuit. The CVM monitors an abnormality of an internal logic circuit, and when an abnormality occurs, notifies the MCU reset control circuit of the abnormality. The MCU reset control circuit transitions the MCU to a reset state in response to the abnormality notification from the CVM. Further, the MCU reset control circuit releases the reset of the MCU in response to a terminal reset signal received at an external terminal.

### SUMMARY

For example, a system including a semiconductor device typified by an MCU (Micro Controller Unit) and an external device controlled by the MCU is widely used. In such a system, when the MCU is initialized, it is usually necessary to also initialize the external device to be controlled by the MCU. For this reason, the MCU may have a function of outputting a reset signal to the external device. Hereinafter, such a function is referred to as a reset-out.

The reset-out can be realized, for example, by using a general-purpose I/O terminal of the MCU. However, in this case, one general-purpose I/O terminal that is originally freely usable by a user is occupied. On the other hand, an MCU usually has a reset terminal to which a reset signal from outside is input. Accordingly, a configuration in which the reset terminal is shared between the reset input from outside and the reset-out to an external device is conceivable. However, in this case, there is a risk that an excessively long reset-out period may be applied to the external device, which could delay the startup of the external device.

Embodiments to be described below have been made in view of such circumstances, and other problems and novel features will be apparent from the description of the present specification and the accompanying drawings.

A semiconductor device according to one embodiment includes an external terminal, a switch, and a pulse generation circuit. The external terminal is a terminal capable of outputting a reset-out signal to an external device. The switch applies a reset voltage to the external terminal during an ON-state period, thereby controlling the reset-out signal to the reset voltage corresponding to an assertion level. The internal reset generation circuit asserts a reset request signal when a reset factor is detected. The pulse generation circuit generates a reset-out drive pulse signal and controls the switch to an ON state/OFF state during an assertion period/negation period of the reset-out drive pulse signal. Here, the pulse generation circuit includes a clock generation circuit, a reset-out period setting register, and a counter. The clock generation circuit generates a clock signal. The reset-out period setting register holds a count setting value representing a length of the assertion period of the reset-out drive pulse signal. The counter counts the clock signal starting from assertion of the reset request signal until the count setting value is reached, thereby generating the reset-out drive pulse signal.

According to the embodiment described above, the startup of an external device at the time of reset can be made faster, while suppressing use of external terminals associated with reset.

### BRIEF DESCRIPTION OF THE DRAWINGS

FIG. 1 is a schematic diagram illustrating a configuration example of a system including a semiconductor device according to a first embodiment.

FIG. 2 is a diagram illustrating a setting example for a reset-out period setting register in FIG. 1.

FIG. 3 is a timing chart illustrating a schematic operation example of a pulse generation circuit in FIG. 1.

FIG. 4 is a flowchart illustrating an operation example at the time of power-on in a control device illustrated in FIG. 1.

FIG. 5 is a flowchart illustrating an operation example when a reset request occurs in the control device illustrated in FIG. 1.

FIG. 6 is a timing chart illustrating an operation example at the time of reset in the system illustrated in FIG. 1.

FIG. 7 is a schematic diagram illustrating a configuration example of a system including a semiconductor device according to a second embodiment.

FIG. 8 is a flowchart illustrating an operation example at the time of power-on in a control device illustrated in FIG. 7.

FIG. 9 is a schematic diagram illustrating a configuration example of a system including a semiconductor device according to a first comparative example.

FIG. 10 is a schematic diagram illustrating a configuration example of a system including a semiconductor device according to a second comparative example.

FIG. 11 is a timing chart illustrating an operation example at the time of reset in the system illustrated in FIG. 10.

### DETAILED DESCRIPTION

In the following embodiments, when necessary for the sake of convenience, the description will be divided into a plurality of sections or embodiments, but unless otherwise specified, the sections or embodiments are not irrelevant to each other, and one is a partial or entire modification, details, supplementary explanation, and the like of the other. In addition, when referring to the number of elements or the like (including number, numerical value, amount, range, and the like), the number of elements is not limited to a specific number unless otherwise specified or obviously limited to the specific number in principle, and the number of elements may be greater than, equal to, or less than the specific number.

Furthermore, in the following embodiments, the components (including element steps and the like) are not necessarily essential unless otherwise specified or considered to be obviously essential in principle. Similarly, when referring to the shape, positional relationship, and the like of the components and the like, it is assumed to include those substantially approximate or similar to the shape and the like unless otherwise specified or unless clearly considered otherwise in principle. The same applies to the above numerical values and ranges.

Hereinafter, embodiments of the present invention will be described in detail with reference to the drawings. In all the drawings for describing the embodiments, the same members are denoted by the same reference numerals in principle, and repetitive descriptions thereof will be omitted.

### First Embodiment

### Outline of Semiconductor Device

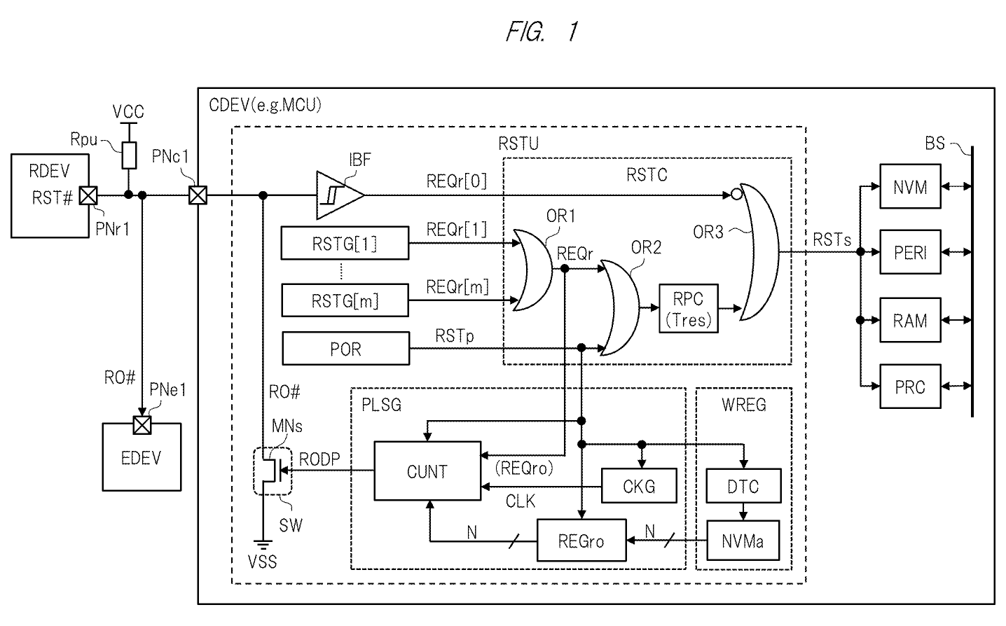

FIG. 1 is a schematic diagram illustrating a configuration example of a system including a semiconductor device according to a first embodiment. The system illustrated in FIG. 1 includes a reset device RDEV, a control device CDEV, and an external device EDEV. As one example, the reset device RDEV is a reset IC provided to reset the entire system. The control device CDEV is a semiconductor device typified by, for example, an MCU or an SoC (System on Chip). The external device EDEV is a device controlled by the control device CDEV.

As terminals related to reset, the reset device RDEV, the control device CDEV, and the external device EDEV include an external terminal PNr1, an external terminal PNc1, and an external terminal PNe1, respectively. The reset device RDEV outputs a reset signal RST# from the external terminal PNr1, which is an output terminal, to the external terminals PNc1 and PNe1 of the control device CDEV and the external device EDEV.

The external terminal PNc1 of the control device CDEV receives the reset signal RST# from the reset device RDEV. In addition, the external terminal PNc1 is a terminal capable of outputting a reset-out signal RO# to the external terminal PNe1 of the external device EDEV. That is, the external terminal PNc1 is a terminal shared for outputting the reset-out signal RO# to the external device EDEV and for receiving the reset signal RST# from outside, here, the reset device RDEV. By asserting the reset-out signal RO#, the control device CDEV can reset the external device EDEV during an assertion period thereof.

For example, an assertion level of the reset-out signal RO# and the reset signal RST# is an “L” level, which is a level of a ground power supply voltage (reset voltage) VSS. For example, the control device CDEV outputs an “L” level from the external terminal PNc1 for a predetermined reset period, and thereafter controls the external terminal PNc1 to a high-impedance state. Similarly, the reset device RDEV also outputs an “L” level from the external terminal PNr1 for a predetermined reset period, and thereafter controls the external terminal PNr1 to a high-impedance state.

In order to cause the reset-out signal RO# or the reset signal RST# to transition to a negation level, here, an “H” level, which is a level of a power supply voltage VCC, in response to the high-impedance state, a high-resistance element such as a pull-up resistor element or a pull-down resistor element is provided. For example, a pull-up resistor element Rpu having one end to which the power supply voltage VCC is applied is provided. In this manner, the external terminal PNc1 of the control device CDEV is also a terminal to which a pull-up resistor element or a pull-down resistor element for controlling the reset-out signal RO# to the negation level can be connected.

The control device CDEV includes a plurality of internal circuits and a bus BS that connects the plurality of internal circuits to each other. Here, the plurality of internal circuits includes a nonvolatile memory NVM, a peripheral circuit PERI, a volatile memory RAM, and a processor PRC. As one example, the nonvolatile memory NVM is an MRAM (Magnetoresistive Random Access Memory) or flash memory. The volatile memory RAM is an SRAM (Static RAM). The processor PRC includes a CPU (Central Processing Unit), and may further include a GPU (Graphics Processing Unit) or a DSP (Digital Signal Processor).

The peripheral circuit PERI is a circuit for implementing various functions required for the control device CDEV. Examples of the peripheral circuit PERI include a communication interface, an analog-to-digital converter, a digital-to-analog converter, and a general-purpose I/O port. The processor PRC executes a program stored in the nonvolatile memory NVM or copied from the nonvolatile memory NVM to the volatile memory RAM. By executing the program stored in the memory, for example, the processor PRC can control the external device EDEV via the peripheral circuit PERI and a corresponding external terminal.

Here, the control device CDEV further includes a reset circuit unit RSTU. The reset circuit unit RSTU outputs a system reset signal RSTs to one or more internal circuits, and also outputs the reset-out signal RO# to the external terminal PNc1. The reset circuit unit RSTU includes an input buffer IBF, m internal reset generation circuits RSTG[1] to RSTG[m], a power-on reset circuit POR, and a reset control circuit RSTC. In addition, the reset circuit unit RSTU includes a register write circuit WREG, a pulse generation circuit PLSG, and a switch SW.

The input buffer IBF receives a signal of the external terminal PNc1 and outputs a reset request signal REQr[0]. As one example thereof, the input buffer IBF receives the reset signal RST# from the reset device RDEV, buffers the reset signal RST#, and then outputs it as the reset request signal REQr[0]. For example, the reset request signal REQr[0] is an “L” pulse signal having an “L” level as an assertion level. Further, the input buffer IBF is specifically configured with, for example, a Schmitt trigger circuit.

The m internal reset generation circuits RSTG[1] to RSTG[m] detect respectively different reset factors. Then, the m internal reset generation circuits RSTG[1] to RSTG[m] respectively assert m reset request signals REQr[1] to REQr[m] when detecting the reset factors. For example, the m reset request signals REQr[1] to REQr[m] are “H” pulse signals having an “H” level as an assertion level. In this specification, the internal reset generation circuits are collectively referred to as an internal reset generation circuit RSTG.

Specific examples of the reset factors include a detection event of voltage drop directed to the power supply voltage VCC or an internal power supply voltage generated from the power supply voltage VCC. In addition, the examples further include a detection event of increase/decrease directed to an ambient temperature detected using a built-in temperature sensor. Moreover, the examples further include a detection event of abnormal operation in the processor PRC and a detection event of an error in the memory. The internal reset generation circuit RSTG detects various abnormalities occurring in the device represented by such reset factors.

The power-on reset circuit POR detects power-on of the control device CDEV and generates a power-on reset signal RSTp when power-on is detected. As is generally known, the power-on reset signal RSTp is a signal for initializing the entire control device CDEV at the time of power-on. For example, the power-on reset signal RSTp is also an “H” pulse signal having an “H” level as an assertion level.

The reset control circuit RSTC asserts the system reset signal RSTs to an “H” level in response to assertion of any one of m+1 reset request signals REQr[0] to REQr[m] or the power-on reset signal RSTp. Then, the reset control circuit RSTC maintains this assertion level for a predetermined reset period. The one or more internal circuits described above are placed into a reset state during the period when the system reset signal RSTs is at the assertion level, that is, during the “H” level period, and are released from the reset state in response to a transition from the “H” level to the “L” level.

Specifically, the reset control circuit RSTC includes three OR gates OR1 to OR3 and a reset period compensation circuit RPC. The OR gate OR1 performs an OR operation on the m reset request signals REQr[1] to REQr[m] from the m internal reset generation circuits RSTG, and outputs an operation result as a reset request signal REQr. The OR gate OR2 performs an OR operation on the reset request signal REQr from the OR gate OR1 and the power-on reset signal RSTp from the power-on reset circuit POR.

The reset period compensation circuit RPC is provided on a signal path from the internal reset generation circuits RSTG to the one or more internal circuits, and is provided between the two OR gates OR2 and OR3 for example. The reset period compensation circuit RPC receives a signal from the OR gate OR2, here an “H” pulse signal, and compensates an “H” pulse width of the “H” pulse signal. A length of a reset period Tres in the one or more internal circuits is determined by the “H” pulse width.

Accordingly, the reset period compensation circuit RPC compensates the length of the reset period Tres required for the one or more internal circuits. That is, the length of the reset period Tres compensated by the reset period compensation circuit RPC is determined based on the longest reset period required among the one or more internal circuits. Note that the length of the reset period Tres may be, for example, on the order of several milliseconds (msec).

The OR gate OR3 performs an OR operation on the “H” pulse signal from the reset period compensation circuit RPC and an “H” pulse signal obtained by inverting the reset request signal REQr[0] from the input buffer IBF. Then, the OR gate OR3 outputs an operation result as the system reset signal RSTs to the one or more internal circuits. At this time, an “H” pulse width of the inverted signal of the reset request signal REQr[0] is determined by the reset device RDEV.

The switch SW applies the ground power supply voltage VSS, which is a reset voltage, to the external terminal PNc1 during an ON-state period. Thus, the switch SW controls the reset-out signal RO# output from the external terminal PNc1 to an assertion level corresponding to the reset voltage, here an “L” level, during the ON-state period. The switch SW is configured with, for example, an nMOS transistor MNs. Note that details of the pulse generation circuit PLSG and the register write circuit WREG will be described later.

Semiconductor Device (Comparative Example) and Problems Thereof

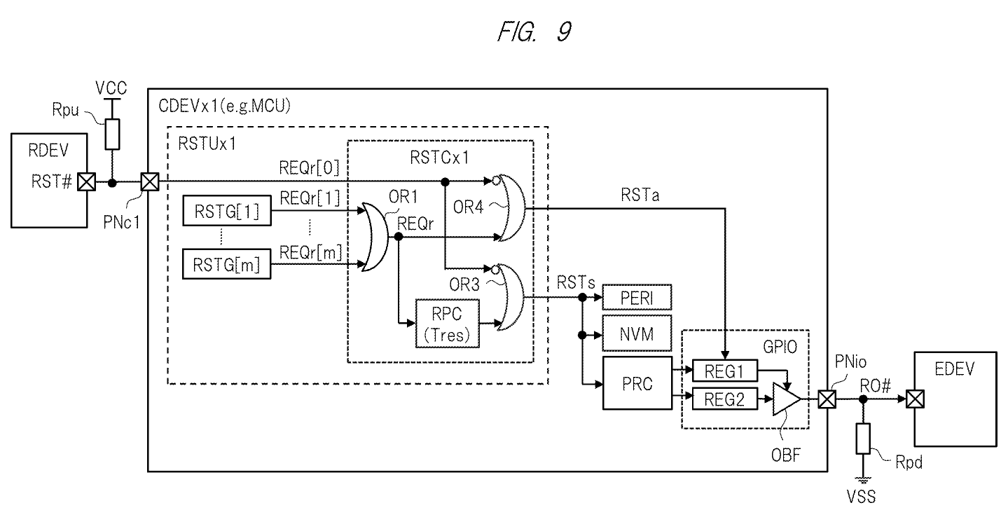

FIG. 9 is a schematic diagram illustrating a configuration example of a system including a semiconductor device according to a first comparative example. The semiconductor device illustrated in FIG. 9, that is, a control device CDEVx1, outputs the reset-out signal RO# to the external device EDEV using a general-purpose I/O port GPIO and a general-purpose I/O terminal PNio unlike the configuration example illustrated in FIG. 1. The control device CDEVx1 includes a reset control circuit RSTCx1 that is substantially the same as that in FIG. 1. However, for simplification of description, illustrations of the input buffer IBF and the power-on reset circuit POR are omitted here.

Further, the reset control circuit RSTCx1 includes an OR gate OR4. The OR gate OR4 performs an OR operation on the reset request signal REQr from the OR gate OR1 and the reset request signal REQr[0] from the external terminal PNc1. Then, the OR gate OR4 outputs an operation result as a register reset signal RSTa to the general-purpose I/O port GPIO.

The general-purpose I/O port GPIO includes two registers REG1 and REG2 and an output buffer OBF. The output buffer OBF outputs the reset-out signal RO# to the general-purpose I/O terminal PNio. An output value of the output buffer OBF is determined by a value of the register REG2. Also, the output buffer OBF is a tri-state buffer whose enable state is controlled by a value of the register REG1, and outputs a high-impedance state when the value of the register REG1 is at an “L” level.

In such a configuration, for example, when the reset request signal REQ is asserted, internal circuits including the processor PRC are placed into a reset state. Further, in parallel with this, the value of the register REG1 is also reset to an “L” level via the register reset signal RSTa. As a result, the general-purpose I/O terminal PNio is set to a high-impedance state, and the reset-out signal RO# becomes an “L” level via a pull-down resistor element Rpd. Consequently, the external device EDEV is also placed into a reset state.

Thereafter, the reset state of the processor PRC is released through the reset period Tres based on the reset period compensation circuit RPC. The processor PRC released from the reset state writes an “H” level to the register REG2 based on a program, and subsequently writes an “H” level also to the register REG1. As a result, the reset-out signal RO# transitions from an “L” level to an “H” level, whereby the reset state of the external device EDEV is also released.

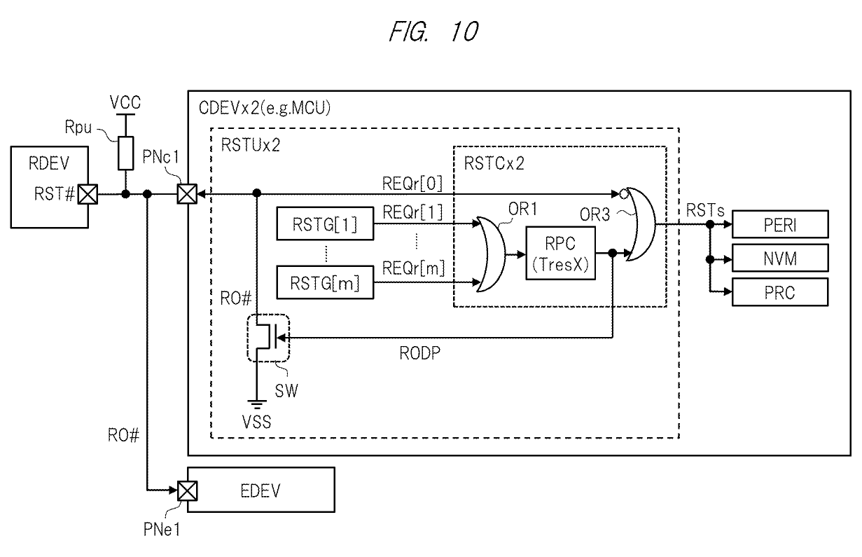

However, when such a configuration is employed, one general-purpose I/O terminal PNio that is originally freely usable by a user is occupied. Accordingly, as illustrated in FIG. 10, a configuration in which the external terminal PNc1 which is originally an input terminal for the reset signal RST# from outside is shared as an output terminal for the reset-out signal RO# as in the case of FIG. 1 is conceivable.

FIG. 10 is a schematic diagram illustrating a configuration example of a system including a semiconductor device according to a second comparative example. A control device CDEVx2 illustrated in FIG. 10 includes a switch SW similar to that in the case of FIG. 1 with respect to the configuration example illustrated in FIG. 9. The switch SW in an ON state asserts the reset-out signal RO# to an “L” level by applying the ground power supply voltage VSS to the external terminal PNc1.

At this time, it is necessary to secure the reset-out period which is a period in which the reset-out signal RO# is at the “L” level by the length based on specifications of the external device EDEV. In FIG. 10, the length of the reset-out period is secured using the reset period compensation circuit RPC. That is, the reset period compensation circuit RPC determines not only the “H” pulse width of the system reset signal RSTs, but also the “L” pulse width of the reset-out signal RO#. Specifically, the reset period compensation circuit RPC controls ON/OFF of the switch SW by outputting a reset-out drive pulse signal RODP.

In this case, a length of a reset period TresX based on the reset period compensation circuit RPC is determined based on specifications of internal circuits that are reset by the system reset signal RSTs and specifications of the external device EDEV that is reset by the reset-out signal RO#. Specifically, the length of the reset period TresX is set to a longest length among lengths based on the respective specifications. However, in such a case, particularly, there is a risk that the reset-out period becomes excessively long, which could delay the startup of the external device EDEV.

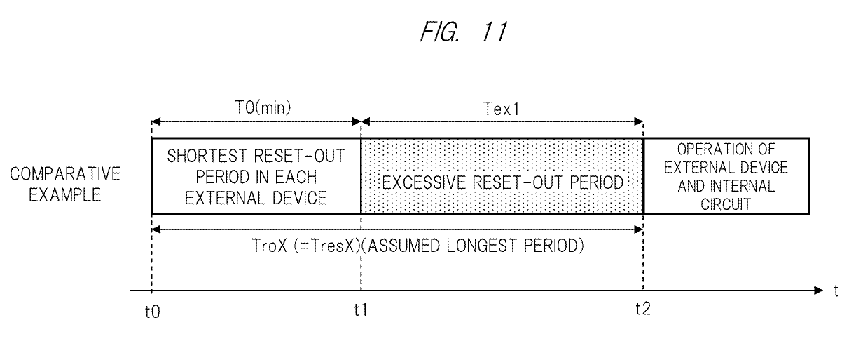

FIG. 11 is a timing chart illustrating an operation example at the time of reset in the system illustrated in FIG. 10. In FIG. 11, a length of a reset-out period TroX is equal to the length of the reset period TresX based on the reset period compensation circuit RPC. Further, as described above, the lengths of the reset period TresX and the reset-out period TroX are set to the assumed longest length.

For example, a case in which either an external device (A) that requires a long reset-out period or an external device (B) that requires only a short reset-out period can be connected to the control device CDEVx2 is assumed. Further, a case in which a length of the reset-out period required by the external device (A) is longer than a length required by internal circuits in the control device CDEVx2 is assumed. In this case, lengths of the reset period TresX and the reset-out period TroX are determined based on the length required by the external device (A).

Then, as illustrated in FIG. 11, when only the external device (B) that requires only a short reset-out period T0(min) is connected to the control device CDEVx2, an excessive reset-out period Tex1 occurs. As a result, as indicated by time t2, startup of the external device (B) is delayed.

As another example, a case in which an assumed longest length is determined based on internal circuits in the control device CDEVx2 is assumed. In this case, startup of the external device EDEV is delayed due to conditions of the internal circuits. Startup of the external device EDEV is preferably earlier. As one example, when the external device EDEV is a sensor device, faster startup enables stable sensing at an earlier stage. Accordingly, the control device can also obtain stable sensing results at an earlier stage.

### Details of Pulse Generation Circuit and Register Write Circuit

Thus, the control device CDEV illustrated in FIG. 1 includes the pulse generation circuit PLSG and the register write circuit WREG. The pulse generation circuit PLSG generates the reset-out drive pulse signal RODP. Then, the pulse generation circuit PLSG controls the switch SW to an ON state/OFF state during an assertion period/negation period of the reset-out drive pulse signal RODP, the assertion period/negation period being an “H” level period/“L” level period for example.

In more detail, the pulse generation circuit PLSG includes a clock generation circuit CKG, a reset-out period setting register REGro, and a counter CUNT. The clock generation circuit CKG generates a clock signal CLK. Note that the clock generation circuit CKG may be a part of an internal clock generator that is normally provided in the control device CDEV. The reset-out period setting register REGro holds a count setting value N representing a length of the assertion period of the reset-out drive pulse signal RODP.

The counter CUNT, in other words, a timer, receives the reset request signal REQr from the OR gate OR1 as a reset-out request signal REQro. Then, the counter CUNT counts the clock signal CLK starting from assertion of the reset-out request signal REQro, and thus assertion of the reset request signal REQr, until the count setting value N is reached. In this manner, the counter CUNT generates the reset-out drive pulse signal RODP. Note that the counter CUNT, the clock generation circuit CKG, and the reset-out period setting register REGro are initialized in response to the power-on reset signal RSTp.

The register write circuit WREG includes a nonvolatile memory NVMa and a data transfer circuit DTC. The count setting value N described above is stored in advance in the nonvolatile memory NVMa. The data transfer circuit DTC transfers the count setting value N stored in the nonvolatile memory NVMa to the reset-out period setting register REGro in response to a power-on reset, that is, the power-on reset signal RSTp.

Here, the control device CDEV may generally include a reset transfer circuit for performing various initial settings for the entire control device CDEV in response to a power-on reset. Such a reset transfer circuit may be implemented by, for example, a combination of a nonvolatile memory and a data transfer circuit. Accordingly, the register write circuit WREG may be a part of the reset transfer circuit.

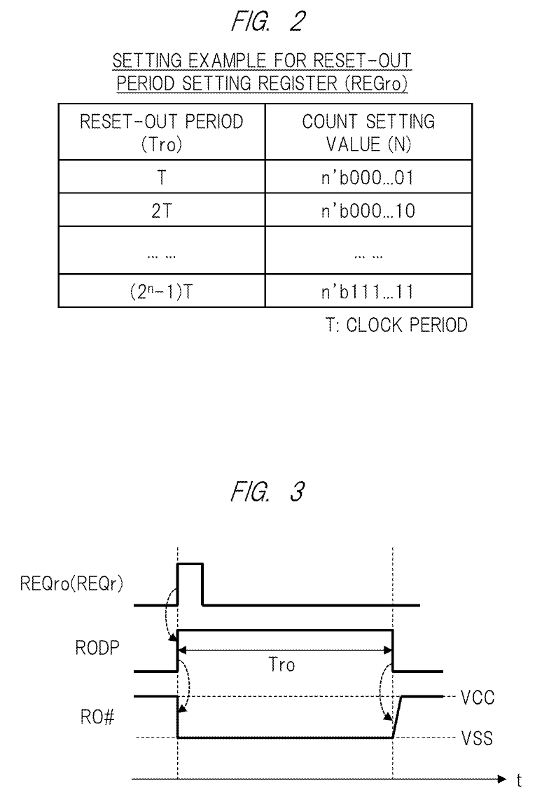

FIG. 2 is a diagram illustrating a setting example for the reset-out period setting register REGro in FIG. 1. In FIG. 2, one period of the clock signal CLK is defined as “T”, and a reset-out period Tro can be arbitrarily set within a range from “T” to “(2ⁿ−1)T” in units of “T”. For example, when the reset-out period Tro is set to “T”, the count setting value N that is an n-bit binary is “000…01”, and when the reset-out period Tro is set to “(2ⁿ−1)T”, the count setting value N is “111…11”. Such values are stored as the count setting value N in advance in the nonvolatile memory NVMa.

FIG. 3 is a timing chart illustrating a schematic operation example of the pulse generation circuit PLSG in FIG. 1. As illustrated in FIG. 3, the pulse generation circuit PLSG asserts the reset-out drive pulse signal RODP to an “H” level in response to assertion of the reset-out request signal REQro, and thus assertion of the reset request signal REQr, to an “H” level. Accordingly, the switch SW is turned on, whereby the reset-out signal RO# transitions from an “H” level to an “L” level, that is, from a level of the power supply voltage VCC to a level of the ground power supply voltage VSS.

Further, the pulse generation circuit PLSG starts a counting operation in response to the assertion of the reset-out request signal REQro to the “H” level. Then, when a count value reaches the count setting value N, the pulse generation circuit PLSG negates the reset-out drive pulse signal RODP to an “L” level. Accordingly, the switch SW is turned off, whereby the reset-out signal RO# transitions from the “L” level to the “H” level by the pull-up resistor element Rpu. The reset-out period Tro is determined by an “L” pulse width of the reset-out signal RO#, and thus by an “H” pulse width of the reset-out drive pulse signal RODP.

### Operation of Semiconductor Device Control Device

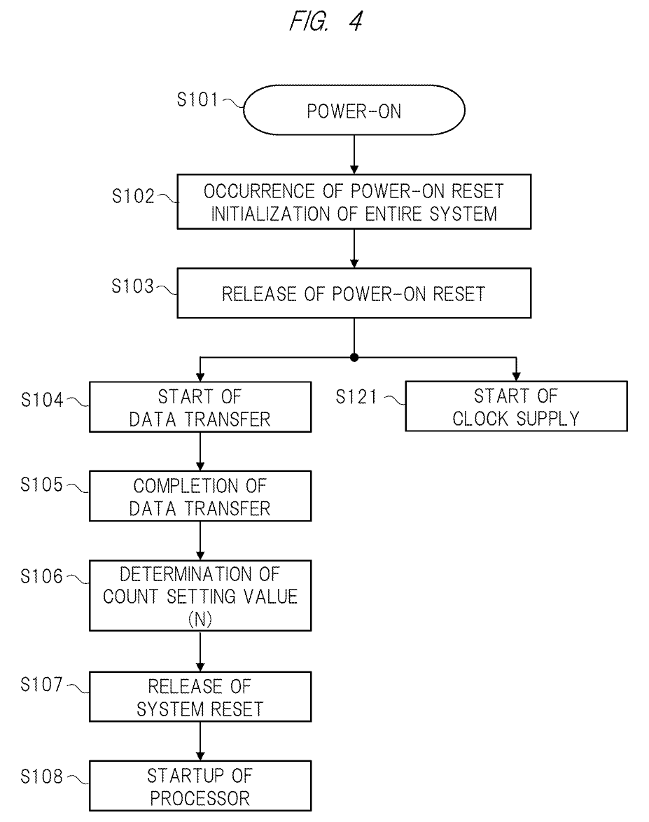

FIG. 4 is a flowchart illustrating an operation example at the time of power-on in the control device illustrated in FIG. 1. In FIG. 4, first, power is supplied to the control device CDEV (step S101). The power-on reset circuit POR detects the power-on and starts initialization of the entire system in the device by asserting the power-on reset signal RSTp (step S102). As a part of this process, the reset control circuit RSTC asserts the system reset signal RSTs.

Subsequently, the power-on reset circuit POR releases the power-on reset state by negating the power-on reset signal RSTp (step S103). In response to this, the data transfer circuit DTC starts data transfer from the nonvolatile memory NVMa to the reset-out period setting register REGro (step S104). In addition, the clock generation circuit CKG starts supplying the clock signal CLK (step S121).

Then, when the data transfer in step S104 is completed (step S105), the count setting value N in the reset-out period setting register REGro is determined (step S106). Thereafter, the reset control circuit RSTC releases the system reset state by negating the system reset signal RSTs after the reset period Tres set in advance has elapsed (step S107). In response to this, the processor PRC starts up, and the operation by the processor PRC is started (step S108).

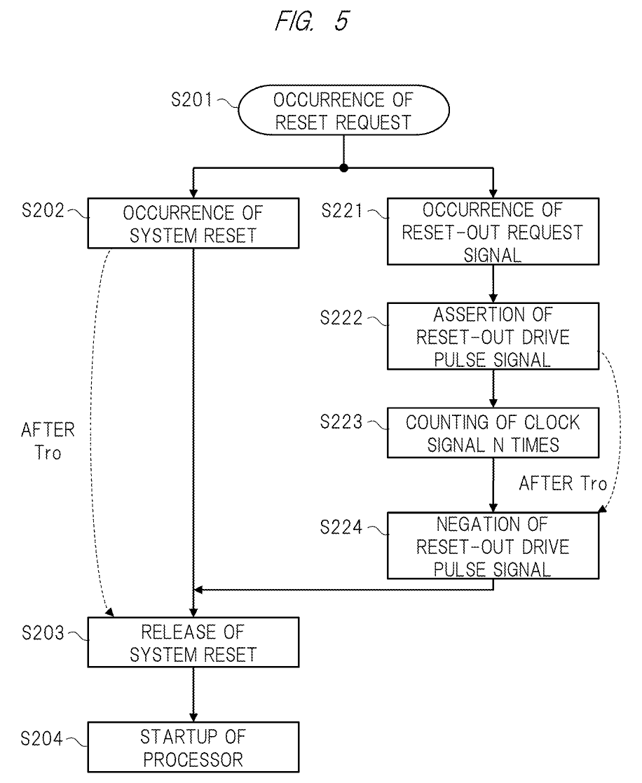

FIG. 5 is a flowchart illustrating an operation example when a reset request occurs in the control device illustrated in FIG. 1. In FIG. 5, first, when a predetermined reset factor is detected, the internal reset generation circuit RSTG asserts the reset request signal REQr (step S201). In response to this, the reset control circuit RSTC asserts the system reset signal RSTs (step S202) and also asserts the reset-out request signal REQro (step S221).

The pulse generation circuit PLSG asserts the reset-out drive pulse signal RODP in response to the assertion of the reset-out request signal REQro (step S222). Then, the pulse generation circuit PLSG counts the clock signal CLK until a count value reaches the count setting value N stored in the reset-out period setting register REGro (step S223). When the count value reaches the count setting value N, the pulse generation circuit PLSG negates the reset-out drive pulse signal RODP (step S224). The period from step S222 to step S224 corresponds to the reset-out period Tro.

On the other hand, after asserting the system reset signal RSTs in step S202, the reset control circuit RSTC negates the system reset signal RSTs after the reset period Tres based on the reset period compensation circuit RPC has elapsed (step S203). In response to this, the processor PRC is started up as the reset state is released (step S204).

Note that a case in which the reset-out period Tro based on the count setting value N is shorter than the reset period Tres based on the reset period compensation circuit RPC has been described here as an example. In this case, the “H” pulse width of the system reset signal RSTs is determined based on an input on the side of the reset period compensation circuit RPC of the OR gate OR3. On the other hand, when the reset-out period Tro based on the setting is longer than the reset period Tres based on the setting, the “H” pulse width of the system reset signal RSTs is determined based on an input on the other side of the OR gate OR3. That is, in this case, the actual reset period Tres becomes equal to the reset-out period Tro.

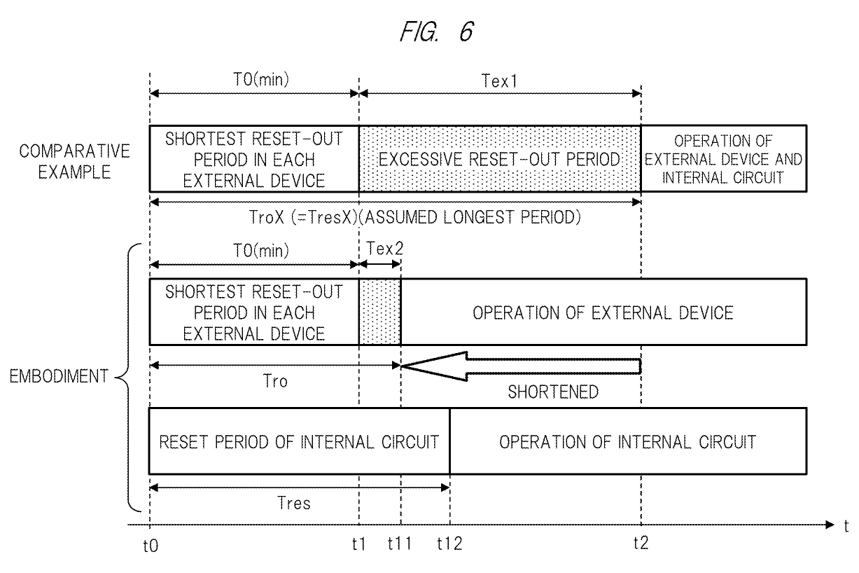

FIG. 6 is a timing chart illustrating an operation example at the time of reset in the system illustrated in FIG. 1. In FIG. 6, the timing chart illustrated in FIG. 11 is also illustrated together as a comparative example. In the comparative example, a length of the reset-out period TorX is determined based on the external device (A) having the longest period described with reference to FIG. 11. On the other hand, when the method of this embodiment is used, the length of the reset-out period Tro can be arbitrarily determined in accordance with the specifications of the external device EDEV connected actually. Therefore, when the external device (B) that requires only a short reset-out period T0(min) is actually connected as in the case of FIG. 11, the reset-out period Tro corresponding thereto can be set.

In the example illustrated in FIG. 6, the length of the reset-out period Tro is set to, for example, a length obtained by adding a margin to the reset-out period T0(min). A length of an excessive reset-out period Tex2 can be the length of this margin. As a result, the excessive reset-out period Tex1 that could occur in the comparative example can be significantly shortened. Accordingly, as indicated by times t11 and t2, startup of the external device EDEV can be made faster by the time corresponding to the shortened excessive reset-out period. Further, for example, as indicated by times t12 and t2, startup of internal circuits in the control device CDEV can also be made faster as compared with the comparative example.

### Modifications

FIG. 1 illustrates a case in which one external device EDEV is connected to the external terminal PNc1 as an example. However, a plurality of external devices EDEV may be connected in parallel to the external terminal PNc1. In this case, the count setting value N is determined based on the longest length of the plurality of reset-out periods required by the plurality of external devices EDEV.

### Main Effects of First Embodiment

As described above, in the first embodiment, a switch for outputting a reset-out signal from an external terminal to which an external device can be connected and a pulse generation circuit that variably controls an on-time of the switch based on a count setting value are provided. As a result, startup of an external device at the time of reset can be made faster, while suppressing use of external terminals associated with reset.

### Second Embodiment

### Outline of Semiconductor Device

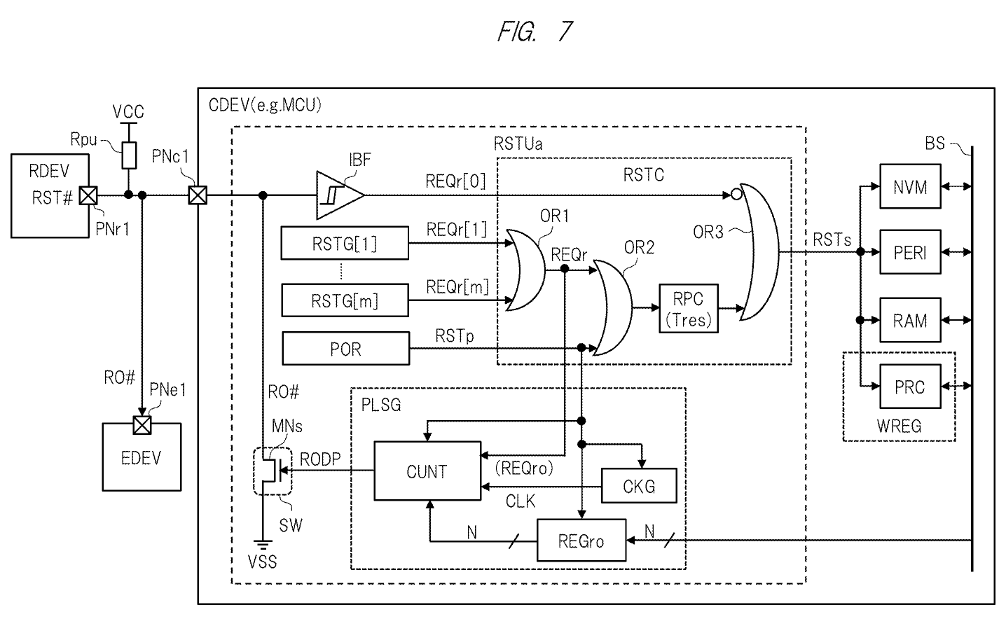

FIG. 7 is a schematic diagram illustrating a configuration example of a system including a semiconductor device according to a second embodiment. The system illustrated in FIG. 7 is different from the system illustrated in FIG. 1 in the configuration of the register write circuit WREG in the control device (semiconductor device) CDEV. In FIG. 7, the register write circuit WREG is implemented by the processor PRC.

As described above, the processor PRC is reset by the system reset signal RSTs. After power-on, that is, after being reset by the system reset signal RSTs corresponding to the power-on reset signal RSTp, the processor PRC executes a program stored in memory. Based on the program, the processor PRC writes, for example, the count setting value N to the reset-out period setting register REGro via the bus BS.

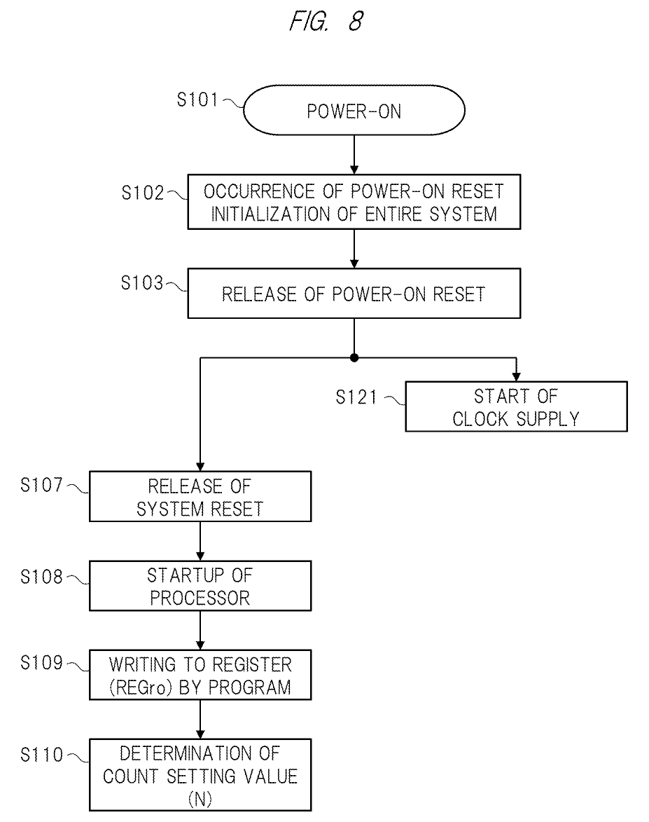

FIG. 8 is a flowchart illustrating an operation example at the time of power-on in the control device illustrated in FIG. 7. In FIG. 8, as in the case of FIG. 4, the control device CDEV starts initialization of the entire system by a power-on reset accompanying power-on, and then releases the power-on reset state (steps S101 to S103). In response to this, the clock generation circuit CKG starts supplying the clock signal CLK (step S121). On the other hand, in FIG. 8, unlike the case of FIG. 4, data transfer in response to release of the power-on reset state (steps S104 to S106) is not performed.

Thereafter, as in the case of FIG. 4, the system reset state is released after the reset period Tres has elapsed, the processor PRC starts up, and the operation by the processor PRC is started (steps S107 and S108). Then, at the time of startup, the processor PRC writes the count setting value N to the reset-out period setting register REGro based on a startup program (step S109). As a result, the count setting value N in the reset-out period setting register REGro is determined (step S110).

### Main Effects of Second Embodiment

As described above, by using the method of the second embodiment, effects similar to the various effects described in the first embodiment can be obtained. Furthermore, since the count setting value can be determined by a program, for example, the count setting value, that is, the reset-out period, can be dynamically changed during a normal operation period after power-on.

On the other hand, unlike the method of the second embodiment, the method of the first embodiment allows the count setting value to be determined before startup of the processor PRC. Therefore, for example, the reset-out signal can be generated even when some reset factor occurs after power-on and before startup of the processor PRC. Thus, from a viewpoint of enabling the reset-out signal early, the method of the first embodiment is advantageous.

Although the invention made by the inventors of this application has been specifically described above based on the embodiments, the present invention is not limited to the above embodiments, and various modifications can be made within the range not departing from the gist of the present invention. For example, the above embodiments have been described in detail so as to make the present invention easily understood, and the present invention is not necessarily limited to those having all the described configurations. In addition, a part of a configuration of one embodiment can be replaced with a configuration of another embodiment, and a configuration of another embodiment can be added to a configuration of one embodiment. In addition, it is possible to add, delete, and replace other configurations for a part of a configuration of each embodiment.

What is claimed is:

1. A semiconductor device comprising:
an external terminal capable of outputting a reset-out signal to an external device;
a switch configured to apply a reset voltage to the external terminal during an ON-state period, thereby controlling the reset-out signal to the reset voltage corresponding to an assertion level;
an internal reset generation circuit configured to assert a reset request signal when a reset factor is detected; and
a pulse generation circuit configured to generate a reset-out drive pulse signal and control the switch to an ON state/OFF state during an assertion period/negation period of the reset-out drive pulse signal,
wherein the pulse generation circuit includes:
a clock generation circuit configured to generate a clock signal;
a reset-out period setting register configured to hold a count setting value representing a length of the assertion period of the reset-out drive pulse signal; and
a counter configured to count the clock signal starting from assertion of the reset request signal until the count setting value is reached, thereby generating the reset-out drive pulse signal.

2. The semiconductor device according to claim 1,
wherein the external terminal is a terminal shared between output of the reset-out signal to the external device and input of the reset signal from outside.

3. The semiconductor device according to claim 2,
wherein the external terminal is a terminal to which a pull-up resistor element or a pull-down resistor element for controlling a reset-out signal to a negation level can be connected.

4. The semiconductor device according to claim 2, further comprising:
a nonvolatile memory in which the count setting value is stored; and
a data transfer circuit configured to transfer the count setting value stored in the nonvolatile memory to the reset-out period setting register in response to a power-on reset.

5. The semiconductor device according to claim 2, further comprising:
a memory in which a program is stored; and
a processor which is reset by a system reset signal,
wherein the processor is reset by the system reset signal in response to power-on, and then writes the count setting value to the reset-out period setting register by executing the program.

6. The semiconductor device according to claim 1, further comprising:
one or more internal circuits which is reset in response to the assertion of the reset request signal; and
a reset period compensation circuit provided on a signal path from the internal reset generation circuit to the one or more internal circuits and configured to compensate a length of a reset period required for the one or more internal circuits.
